(19) United States
(12) Patent Application Publication
(10) Pub. No.: US 2004/0070043 A1
(43) Pub. Date: Apr. 15, 2004

(54) CMOS image sensors

(76) Inventors: In Gyun Jeon, Seoul (KR); Jinsu Han, Seoul (KR)

Correspondence Address: GROSSMAN & FLIGHT LLC, Suite 4220, 20 North Wacker Drive, Chicago, IL, 60606-6357, US

(21) Appl. No.: 10/442,613

(22) Filed: May 21, 2003

(30) Foreign Application Priority Data
May 22, 2002 (KR) 10-2002-28464

(51) Int. Cl. H01L 31/06

(52) U.S. Cl. 257/461; 257/464; 257/465; 257/466

(57) ABSTRACT

A CMOS image sensor is disclosed which has a photodiode formed by implanting ions into an area of a substrate. The photodiode surface area corresponds to about 15% to 40% of the surface area of a photoreceptor part region of the sensor. Thus, the capacitance associated with the photodiode is reduced relative to prior art photodiodes, and, thus, the output signals generated by the detected light are increased. Further, by reducing the size of the photodiode in manufacturing the CMOS image sensor, the junction region is reduced to thereby improve the absorption efficiency of light and high integration of the CMOS image sensor can be achieved to thereby prevent deterioration of device characteristics.

### FIELD OF THE DISCLOSURE

The present disclosure relates to image sensors; and, more particularly, to CMOS image sensors.

### BACKGROUND

Every material reflects light to some degree. Light has different colors depending on its wavelength. Each different wavelength of visible light causes human eyes to see a different color. The longest wavelength humans can see is red while the shortest wavelength humans can detect is violet. An object penetration depth of light is also different depending on the wavelength of the light. That is, the object penetration depth gets longer as the wavelength of the light increases while the object penetration depth is shortened as the wavelength decreases.

Image sensors utilize this object penetration depth property of light. In earlier times, charge coupled devices (CCD) were widely utilized to implement image sensors. However, the use of CCDs to form image sensors has many disadvantages. For example, it involves a very complicated manufacturing process, a low yield and a high unit cost of production. Thus, as an alternative to using CCDs to implement image sensors, it has been suggested to manufacture CMOS image sensors by employing a CMOS process.

A photodiode is a device designed to be responsive to optical input. If light is eradiated on the photodiode, electron-hole pairs (EHPs) are created and a current is generated as a result of a difference in carrier concentration. If the intensity of the light is increased, a greater amount of EHPs are created. Conversely, the amount of EHPs created is reduced if the light intensity is decreased. As is known, electrical current is dependent on the quantity of EHPs passing through a unit area. Thus, the current is increased if the quantity of the EHPs increases and, conversely, the current is reduced if the quantity of the EHPs decreases. Accordingly, a rise in the light intensity causes an increase in the current amount and vice versa.

In the prior art CMOS image sensor based on the above-described principle, a photodiode serving as a photoreceptor part for converting received light into an electric signal is manufactured as follows. The description of that process will be provided with reference to FIGS. 1A to 1C, which are flowcharts describing a prior art manufacturing process of the photodiode of the CMOS sensor.

It is assumed herein that the photodiode has a PN junction structure, which is the most widely employed photodiode structure.

First, an element isolation layer 12 is formed in a predetermined region of a semiconductor substrate 11 by using a LOCOS (local oxidation of silicon) process. Then, an N-type photodiode ion implantation process is performed in order to form a photodiode in a predetermined region of the semiconductor substrate 11. In the N-type photodiode ion implementation process, N-type impurities are implanted into a certain area on the semiconductor substrate 11, thereby forming an impurities area 13, as shown in FIG. 1A. The impurities area 13 serves as a photoreceptor part for absorbing incident light.

Thereafter, the impurities implanted in the impurities area 13 are diffused by a preset heating process, so that the upper portion of the P-type semiconductor substrate 11 becomes doped with the N-type impurities, as shown in FIG. 1B. The obtained N-type doped portion of the P-type semiconductor substrate 11 serves as a PN diode, which is used as a photodiode 13′ as shown in FIG. 1B.

If a reverse potential is applied to the N-type doped photodiode 13′, a depletion region 14 is formed as illustrated in FIG. 1C. Further, electron hole pairs (EHPs) are formed within the depletion region 14 due to the light absorbed by the depletion region 14 through the photodiode 13′. The CMOS image sensor performs its sensing operations by measuring the amount of electrons among the carriers of the EHPs.

Conventional CMOS image sensors, however, have the following drawbacks. Though prior art CMOS image sensors are useful to detect light having a comparatively long wavelength with a long object penetration depth, it cannot effectively detect light having a short wavelength with a short object penetration depth, such as light having a blue color. Thus, if light having a short wavelength is involved, the light may be lost without contributing to the output signals generated by the prior art image sensor. Further, since the area of the photodiode 13′ on which the junction is formed is large in the conventional CMOS image sensor, the capacity value of the photodiode is also large, which in turn causes a decrease in potential difference (i.e., V=Q/C), resulting in a reduction of the output signal value.

Referring to FIG. 2, there is illustrated a prior art CMOS image sensor fabricated through the photodiode formation process described above. The prior art CMOS image sensor shown in FIG. 2 includes (a) a boundary region 10 which is a virtual interface area between unit pixels, (b) the photodiode 13′, which is positioned within the boundary region 10 for detecting light, (c) a photoreceptor part 20 for receiving electrons generated by the light detected by the photodiode 13′ and storing therein the received electrons, and (d) a circuit 30 for detecting a voltage level of the electrons stored in the photoreceptor part.

Though the photoreceptor part 20 and the photodiode 13′ are shown in FIG. 2 as having different sizes, their sizes are almost identical in practice.

Recently, there has been a tendency to extend the area of the photodiode 13′ and, thus, enlarge the photoreceptor part 20 for receiving light for the purpose of increasing the efficiency of the incident light. However, in addition to the positive effect of incident light efficiency improvement, the size increase of the photodiode 13′ also has negative results such as reduction of signal strength due to the increased capacitance of the photodiode. Furthermore, the extent to which the area of the photodiode 13′ may be extended is limited due to the increase of integration of the sensor.

### BRIEF DESCRIPTION OF THE DRAWINGS

FIGS. 1A to 1C illustrate a prior art process for forming a photoreceptor part of a pixel in a conventional CMOS image sensor;

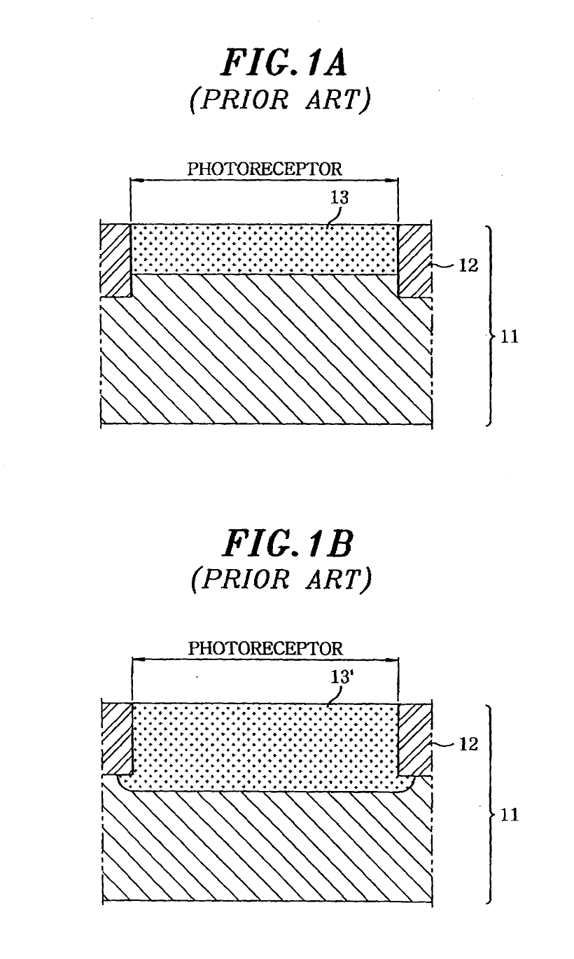

FIG. 2 provides a plan view of a pixel in a conventional CMOS image sensor;

FIGS. 3A to 3C illustrate an example process for forming a photoreceptor part of a pixel in an example CMOS image sensor;

FIG. 4 is a plan view of an example pixel in an example CMOS image sensor;

FIG. 5 is a plan view of another example pixel in a second example CMOS image sensor; and

FIG. 6 is a plan view of another example pixel in a third example CMOS image sensor.

### DETAILED DESCRIPTION

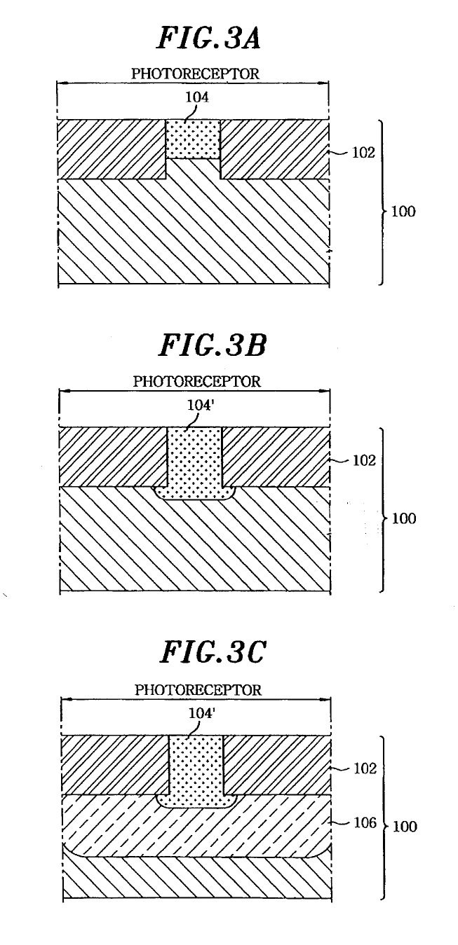

FIG. 4 is a plan view of a unit pixel of an example CMOS image sensor. The unit pixel of the illustrated CMOS image sensor includes a boundary region 110, a photodiode 104′, a photoreceptor part 108 and a circuit portion 109. The boundary region 110 is a virtual interface between unit pixels. The photodiode 104′ is located within the boundary region 110 and detects light. The photoreceptor part 108 receives electrons generated by the detected light and stores therein the received electrons. The circuit potion 109 estimates a voltage level of the electrons stored in the photoreceptor part 108.

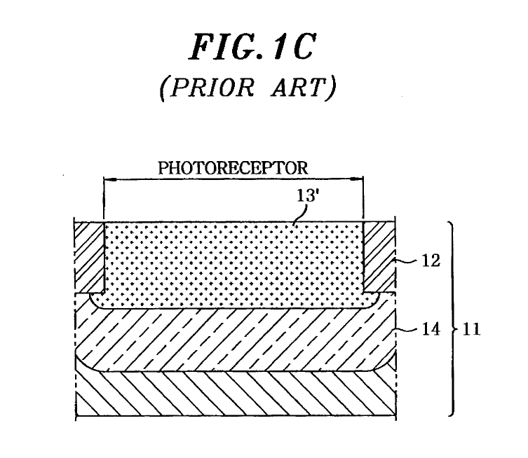

Though the size of the photoreceptor part 108 is identical to that of the photoreceptor part 20 shown in the conventional CMOS image sensor (see FIG. 2), the ion-implanted active region forming the junction region, (i.e., the photodiode 104′), is considerably reduced in size compared to the photodiode 13′ of the prior art sensor. By reducing the size of the photodiode 104′, the capacitance of the associated junction is decreased thereby increasing the light absorption efficiency and, thus, the amount of light input to the ion-implanted junction region can also be reduced while achieving substantially the same output signal strength. As a result, the illustrated sensor is more sensitive and can more effectively detect light, including light of short wavelengths, than prior art sensors.

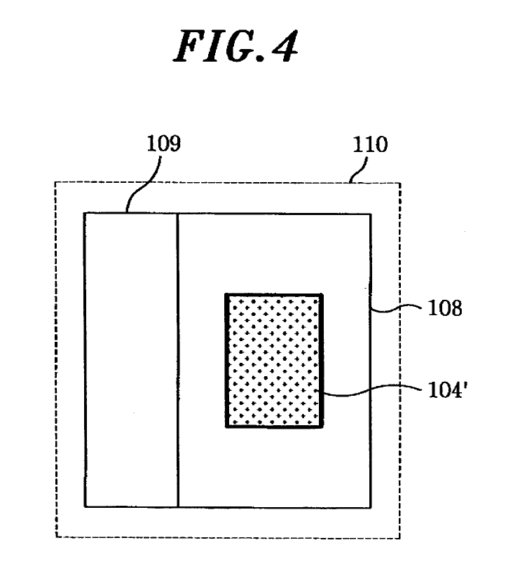

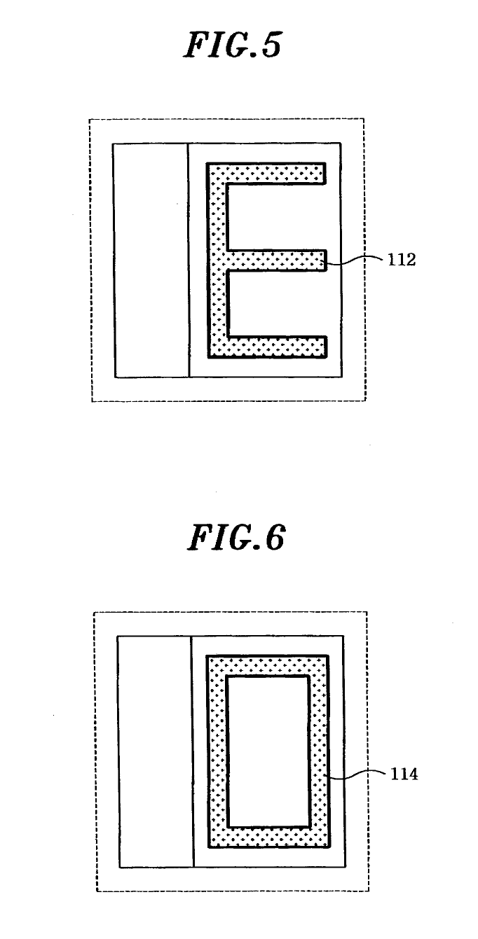

Although the photodiode 104′ has a square shape in the preferred example of FIG. 4, it is also preferable to modify the shape of the photodiode to other closed polygonal shapes, for example, a comb 112 or an annular rectangular shape 114, as shown in FIGS. 5 and 6. By modifying the shape of the photodiode 104′, 112, 114, one adjusts the depletion region, which is created within the semiconductor substrate by a voltage applied to the photodiode 104′, 112, 114.

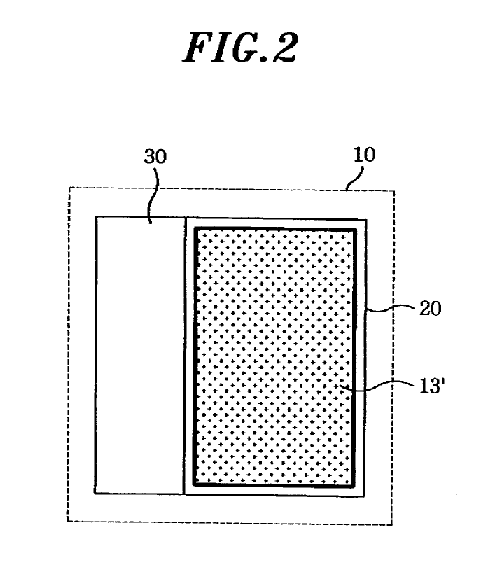

FIGS. 3A to 3C illustrate a process for forming the photodiode 104′ serving as the photoreceptor part in the example CMOS image sensor of FIG. 4. Similar processes may be used to form photodiodes 112, 114 of other shapes, if desired.

First, an element isolation layer 102 is formed in a predetermined region of a semiconductor substrate 100 by employing a LOCOS process. Then, an N-type ion implantation is performed in order to form the photodiode 104′ in the selected region of the semiconductor substrate 100. Specifically, in the ion implantation process, N-type impurities are implanted into the selected region of the semiconductor substrate 100, thereby forming an impurities region 104 as illustrated in FIG. 3A.

The impurities region formation process of the illustrated example is different from the prior art process in that a pre-process for limiting a “to-be-ion-doped” area to a certain portion of the photoreceptor part is performed before the ion plantation process is begun. The pre-process involves, for example, forming a photo-sensitive layer on the certain portion of the photoreceptor part or forming the ion-isolation layer 102 on the entire region of the photoreceptor part except for the area into which the ions are to be implanted.

The size (e.g., the surface area) of the impurities region 104 corresponds to about 15% to 40% of the size (e.g., the surface area) of the photoreceptor part 108. More preferably, the size of the photodiode 104′, 112, 114 formed by conducting the ion implantation process corresponds to about 20% of the size of the photoreceptor part 108. By reducing the size of the photodiode 104′, 112, 114, the capacitance associated with the photodiode, (which is dependent on the size of the photodiode), is also reduced. Further, it is noted that the size of the impurities region 104 does not affect the size of the depletion region formed in the semiconductor substrate 100 by an applied electric potential.

After the impurities region 104 is prepared, a predetermined heating process is performed, whereby the impurities implanted in the impurities region 104 are diffused. As a result, the N-type doped portion in the upper portion of the p-type semiconductor substrate 100 becomes to serve as a PN diode, which is herein used as the photodiode 104′.

If a reverse potential is applied to the N-type doped photodiode 104′, a depletion region 106 is formed as shown in FIG. 3C. Further, electron hole pairs (EHPs) are formed within the depletion region 106 due to the light absorbed into the depletion region 106 through the photodiode 13′. The CMOS image sensor performs its sensing operation by measuring the amount of electrons among the carriers of the EHPs.

As shown in FIG. 3c, the depletion region 106 formed by the reverse potential applied to the photodiode 104′ is formed in the entire region of the semiconductor substrate right below the photoreceptor part region. At this time the area of the depletion region 106 does not exceed that of the photoreceptor part region.

From the foregoing, persons of ordinary skill in the art will appreciate that an example CMOS image sensor has been described which includes: (a) a photoreceptor portion having a photodiode, wherein the photodiode occupies about 15% to about 40% of the photoreceptor portion; and (b) a circuit portion for estimating a voltage level of electrons stored in the photoreceptor portion.

As described above, the illustrated CMOS image sensor reduces the size of the photodiode 104′, 112, 114 without decreasing the area of the photoreceptor part. By reducing the size of the photodiode 104′, 112, 114, the size of the junction region is also reduced. Since the junction region is reduced in its size, the capacitance of the junction region is decreased resulting in an improvement of the light absorption efficiency, so that the amount of incident light required to generate an output signal of equivalent strength is reduced.

Furthermore, by reducing the size of the photodiode 104′, 112, 114 in fabricating the CMOS image sensor, high integration of the CMOS sensor can be achieved and deterioration of device characteristics can be prevented.

Although certain example methods and apparatus have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. A CMOS image sensor comprising:
a photoreceptor portion having a photodiode, wherein the photodiode occupies about 15% to about 40% of the photoreceptor portion; and
a circuit to estimate a voltage level associated with the photoreceptor portion.

2. A CMOS image sensor as defined in claim 1, wherein the photodiode is formed by implanting an N type or a P type dopant.

3. A CMOS image sensor as defined in claim 1, wherein the photodiode occupies about 20% of the photoreceptor portion.

4. A CMOS image sensor as defined in claim 2, wherein the photodiode occupies about 20% of the photoreceptor portion.

5. A CMOS image sensor as defined in claim 1, wherein the photodiode comprises a closed polygonal.

6. A CMOS image sensor as defined in claim 2, wherein the photodiode comprises a closed polygonal.

7. A CMOS image sensor as defined in claim 1, wherein the photodiode has at least one of a comb shape, an annular shape, and a rectangular shape.

8. A CMOS image sensor as defined in claim 2, wherein the photodiode has at least one of a comb shape, an annular shape, and a rectangular shape.
